(19) United States
(12) Patent Application Publication
(10) Pub. No.: US 2019/0138155 A1
(43) Pub. Date: May 9, 2019

(54) ACOUSTIC TOUCH-CONTROL SYSTEM AND HOUSEHOLD APPLIANCE HAVING THE ACOUSTIC TOUCH-CONTROL SYSTEM

(71) Applicant: DIEHL AKO STIFTUNG & CO. KG, WANGEN (DE)

(72) Inventor: YAN LI, NANJING (CN)

(21) Appl. No.: 16/180,213

(22) Filed: Nov. 5, 2018

(30) Foreign Application Priority Data
Nov. 3, 2017 (CN) 201711066880.2

(51) Int. Cl. G06F 3/043; H05K 1/02; G06F 3/041

(52) U.S. Cl. CPC G06F 3/0436; G06F 3/0416; H05K 1/0213

(57) ABSTRACT

A household electric appliance has an acoustic touch-control system. The acoustic touch-control system contains a panel having a touch region and a printed circuit board with an acoustic sensor being disposed on the printed circuit board. The acoustic sensor is respectively allocated to the corresponding touch region. A control apparatus is arranged to receive a signal from the acoustic sensor and subject the signal to further analytical processing. An intermediate body is disposed between the printed circuit board and the panel and formed such that a sound-receiving surface of the acoustic sensor is hermetically isolated from an external environment.

### CROSS-REFERENCE TO RELATED APPLICATION

This application claims the priority, under 35 U.S.C. § 119, of Chinese application CN 201711066880.2, filed Nov. 3, 2017; the prior application is herewith incorporated by reference in its entirety.

### BACKGROUND OF THE INVENTION

### Field of the Invention

The present invention relates to the technical field of household electric appliances, in particular to an acoustic touch-control system and a household electric appliance having the acoustic touch-control system.

In recent years, touch-control systems have been used ever more widely in the field of household electric appliances. Most touch-control systems for household electric appliances currently on the market use capacitive touch panels. Capacitive touch panels operate by using human body current sensing. A capacitive touch panel detects a capacitance change—which arises due to the influence of a touching object (such as a finger)—in a capacitance between two axial sensing electrodes of the touch panel, or in a capacitance between a ground terminal and each of two axial sensing electrodes of the touch panel. Thus, based on the fundamental principles of a capacitive touch panel, there is a series of problems: a capacitive touch panel cannot be made of metal, but instead must be made of a non-conductive material, such as plastic or glass; a touching object must be a conductor in order to influence capacitance—if the touching object is an insulator, then it will not be possible to detect the position of touching; dampness will affect the performance of the capacitive touch panel, but based on the fact that the fields of application of household electric appliances often cause the touch panel surface to be covered in water, the performance of the capacitive touch-control system will suffer significant interference.

In order to resolve the drawbacks of capacitive touch panels, a piezoelectric touch panel is also known in the prior art, wherein a piezoelectric material must be used to make sensing units. Multiple piezoelectric sensing units on a substrate are used to sense external pressure deformation directly, to determine the position of pressing, with no limitations on the touching object. However, based on the fundamental principles of a piezoelectric touch panel, a simple touch or light strike is not enough to produce a deformation amount sufficient to determine the position of touching. Piezoelectric touch panels generally require a large pressure, e.g. 1 N to 3 N. In addition, in order to increase system sensitivity, a piezoelectric material layer must be formed thinly, e.g. with a thickness of about 0.7 mm. This further increases manufacturing difficulty and therefore increases manufacturing costs.

Hence, the development of a touch panel technology which is not affected by dampness or the magnitude of pressure, is suitable for a wide range of touching object types, and can use panels of different material types, is a field worthy of research and development at the present time.

### SUMMARY OF THE INVENTION

The mission of the present invention is to provide a reliable acoustic touch-control system with wide applicability.

In addition, the present invention also provides a household electric appliance having an acoustic touch-control system.

According to one aspect of the present invention, the mission is solved by means of an acoustic touch-control system containing a panel, having one or more touch regions; one or more acoustic sensors, respectively allocated to the corresponding touch region; and a control apparatus, arranged to receive a signal from the acoustic sensor and subject the signal to further analytical processing. One or more intermediate bodies are provided and are capable of hermetically isolating a sound-receiving surface of the acoustic sensor from an external environment.

According to the present invention, the panel has one or more touch regions, and each touch region may represent one function, e.g. a corresponding function may be activated by knocking or tapping the touch region. Here, the acoustic sensor(s) is/are respectively allocated to the corresponding touch region(s), for the purpose of detecting a sound wave generated by knocking or tapping the panel, and sending a corresponding sound wave signal to the control apparatus in a wired or wireless manner. The control apparatus may be arranged to further determine the knocked or tapped touch region by analytical processing of the signal of the acoustic sensor, for the purpose of activating the function represented by the knocked or tapped touch region.

Firstly, since the present invention senses a sound wave generated when a human body or an object knocks or taps the panel, a touching body may involve multiple different types of object, e.g. may be a human body, such as a finger (including a finger wearing a plastic glove);a non-conductive object, such as a plastic object; or a conductive object, such as a metal rod, etc. Hence, compared with a capacitive touch-control system in the prior art, a broader range of touching object types can be used to operate the acoustic touch-control system of the present invention. In addition, since the knocking or tapping of the panel does not suffer interference from dampness or water on the panel, another advantage of the acoustic touch-control system of the present invention over a capacitive touch-control panel is that the former is not affected by dampness. Moreover, the present invention detects a sound wave generated by knocking or tapping the panel, not the size of a force pressing on the panel. Thus, compared with a piezoelectric touch panel, there is no restriction on the size of the force pressing on the panel. In addition, due to the good transmission properties of sound waves in solids, the acoustic touch-control system of the present invention has no restrictions in terms of panel thickness. This also constitutes an advantage of the acoustic touch-control system of the present invention over a piezoelectric touch panel.

It must be explained that the hermetic isolation of the sound-receiving surface of the acoustic sensor from the external environment means that the intermediate body is formed such that no air gap in communication with the external environment is present between the sound-receiving surface of the acoustic sensor and the panel, thereby ensuring that noise from the external environment will not be transmitted via an air gap directly to the sound-receiving surface of the acoustic sensor, and thereby interfere with the acoustic sensor. It must be emphasized that within the scope of the present application, “external environment” should be understood to be an atmospheric environment, i.e. a sound field, in which the entire acoustic touch-control system is located. All interference factors, e.g. noise from a road, etc., in an atmospheric environment or sound field in which the entire acoustic touch-control system is located are excluded through the hermetic isolation of the sound-receiving surface of the acoustic sensor from the external environment. In general, noise from the external environment will hamper analytical processing by the control apparatus, and hence reduce the reliability of the system. For example, noise from the external environment might lead to a specific function being activated when a touch region has not been knocked or tapped. This can be avoided as far as possible by hermetically isolating the sound-receiving surface of the acoustic sensor from the external environment.

Preferably, the acoustic touch-control system further contains a printed circuit board, with the one or more acoustic sensors being disposed on the printed circuit board, and the intermediate body being disposed between the panel and the printed circuit board.

Preferably, the acoustic touch-control system further contains a housing, the housing accommodates the intermediate body, the printed circuit board and the control apparatus. The housing and the panel are formed such that the intermediate body and the printed circuit board are pressed tightly against each other, i.e. hermetic contact between the intermediate body and the printed circuit board is ensured by means of pressure provided by the housing, thereby eliminating an air gap in communication with the external environment and hence improving the resistance of the system to interference.

In addition, when multiple acoustic sensors are present, the one or more intermediate bodies is/are formed such that the sound-receiving surfaces of the multiple acoustic sensors are also hermetically isolated from each other, thereby further improving the performance of the system. Here, it could also be imagined that multiple intermediate bodies are provided, spaced apart from each other by a distance, wherein each intermediate body is respectively allocated to the corresponding acoustic sensor. For example, each intermediate body is respectively allocated to one acoustic sensor, or each intermediate body is respectively allocated to multiple acoustic sensors. What is important is that each intermediate body must ensure that the correspondingly allocated one or more acoustic sensors is/are hermetically isolated from the external environment. Preferably, each intermediate body must also ensure that the correspondingly allocated acoustic sensor is hermetically isolated from other acoustic sensors.

According to the present invention, the intermediate body is in hermetic contact with the sound-receiving surface of the acoustic sensor. Preferably, the hermetic contact may for example be achieved by means of pressure provided by the housing, i.e. by press-joining. As another possibility, the hermetic contact could for example also be achieved by bonding, injection molding, etc.

According to the present invention, the intermediate body circumferentially surrounds the sound-receiving surface of the acoustic sensor. Here, “circumferentially surrounds” may be understood to mean that the sound-receiving surface of the acoustic sensor extends into or is sunk into the intermediate body, such that there is hermetic contact, i.e. no air gap present, between the intermediate body and the sound-receiving surface of the acoustic sensor. “Circumferentially surrounds” may also be understood to mean that the sound-receiving surface of the acoustic sensor is sealed by the intermediate body, i.e. isolated from an environment outside the intermediate body. It must be emphasized here that in the latter case, a cavity sealed with respect to the external environment might be present between the sound-receiving surface of the acoustic sensor and the intermediate body.

According to a preferred embodiment of the present invention, the intermediate body is formed as a planar structure having a blind hole, wherein the depth of the blind hole is less than the thickness of the acoustic sensor, and the acoustic sensor is respectively inserted into the corresponding blind hole, such that the intermediate body is in hermetic contact with the panel only in a partial region, preferably in a boss-like fashion. In this way, not only is it ensured that no air gap is present between the sound-receiving surface of the acoustic sensor and the panel, but there is also no need to ensure that the intermediate body maintains full-surface hermetic contact with the panel; here, it is only necessary to take into account hermetic contact between the panel and the intermediate body in a corresponding blind hole region, i.e. in a region of the sound-receiving surface of the acoustic sensor, thereby ensuring hermetic contact between the sound-receiving surface of the acoustic sensor and the panel in a simple and cost-effective way.

According to a preferred embodiment of the present invention, the intermediate body is formed as a planar structure having a blind hole, wherein the depth of the blind hole is greater than the thickness of the acoustic sensor, and the acoustic sensor is respectively inserted into the corresponding blind hole, such that only a closed cavity is present between the sound-receiving surface of the acoustic sensor and the panel. Here, the presence of an air gap between the sound-receiving surface of the acoustic sensor and the panel prevents the sound-receiving surface of the acoustic sensor from being pressed during system operation due to pressing with a large force or bumping, and therefore protects the acoustic sensor, extending the service life thereof.

In addition, the intermediate body is preferably connected to the printed circuit board and/or the panel by injection molding. Preferably, the intermediate body is injection-molded on the printed circuit board by low-pressure injection molding, so that the printed circuit board (including the acoustic sensor disposed on the printed circuit board) and the intermediate body are integrally formed, and an air gap between the sound-receiving surface of the acoustic sensor and the intermediate member is therefore eliminated. In a similar manner, the intermediate body and the panel may be integrally formed, and an air gap between the intermediate body and the panel is therefore eliminated effectively in a simple process step.

According to the present invention, the intermediate body is connected to the printed circuit board and/or the panel by bonding, in particular by means of a bonding layer, e.g. double-sided adhesive tape. Further sealing can be achieved between the intermediate body and the printed circuit board and/or the panel by bonding, thereby ensuring that no air gap in communication with the external environment is present between the sound-receiving surface of the acoustic sensor and the panel.

According to the present invention, the intermediate body is made of an elastic material, preferably a closed-cell foamed material, and more preferably silicone rubber or foam. Of course, various other types of elastic material conforming to the object of the present invention could also be imagined.

In addition, the Shore hardness of the intermediate body is in the range of 50 to 110, preferably in the range of 70 to 90, and more preferably in the range of 75 to 85. An intermediate body material which is too soft or too hard will affect the performance of the system. If the intermediate body material is too soft, a sound wave produced by knocking or tapping the touch region might be absorbed by the intermediate body, with the result that the acoustic sensor is unable to receive a sound wave signal, or a sound wave signal received is too small so that the control apparatus is unable to make an accurate determination. However, if the intermediate body material is too hard, a sound wave produced by knocking or tapping the touch region might be held in the intermediate body continuously, thereby increasing the difficulty of analytical processing by the control apparatus, and possibly even causing errors in determination by the control apparatus. The hardness selected in the present invention can not only effectively conduct sound wave signals to the acoustic sensor, but also enable sound wave signals to die out within a suitable time period. Here, the “suitable time period” relates to the control apparatus, in order to enable the control apparatus to subject received sound wave signals to further analytical processing effectively.

According to the present invention, the control apparatus is disposed on the printed circuit board. Of course, it is also possible for the control apparatus to be separate from the printed circuit board, e.g. the control apparatus may be disposed on another printed circuit board or disposed in the housing directly. The acoustic sensor may communicate with the control apparatus for example in a wired and/or wireless fashion.

According to the present invention, one or more auxiliary acoustic sensors is/are arranged around the acoustic sensor allocated to the corresponding touch region, for the purpose of improving system reliability. Of course, as another possibility, the acoustic sensor itself could also be used as an auxiliary acoustic sensor of another acoustic sensor. Preferably, the control apparatus can increase the precision with which a touch operation is located on the basis of amplitudes and/or a chronological order and/or phases and/or attenuation characteristics of signals from the acoustic sensor and the auxiliary acoustic sensor. By jointly taking into account a signal from the acoustic sensor, a signal from the auxiliary acoustic sensor and characteristic parameters allocated to the corresponding acoustic sensor, interference factors can be further excluded effectively, increasing the precision with which a touch operation is located and thereby improving system performance. For example, if a sound originates in the household electric appliance itself, then all sensors (acoustic sensor(s) and auxiliary acoustic sensor(s)) will obtain similar signals, and exclusion can be carried out effectively through design of the control apparatus at algorithm level. In a similar manner, erroneous system operation caused by certain erroneous operations may be excluded effectively, e.g. sound waves caused by inadvertently touching a non-touch region.

According to the present invention, the panel may be made of metal, plastic, glass or wood. Compared with a capacitive touch panel, for which a non-conductive material is the only option, an acoustic touch panel has a wider application scope, and there is a more diverse choice of panel materials. Compared with a piezoelectric touch panel, in which a thin piezoelectric material layer must be arranged, an acoustic touch panel has a lower level of manufacturing difficulty and hence lower manufacturing costs. According to the present invention, the acoustic sensor is a microphone, preferably a microelectro-mechanical systems microphone (a MEMS microphone). Of course, various other types of sensor for measuring sound waves could also be imagined.

According to the present invention, the intermediate body is disposed below the panel by press-joining, injection molding or bonding, and the intermediate body is disposed above the printed circuit board by press-joining, injection molding or bonding. The control apparatus communicates with the acoustic sensor disposed on the printed circuit board. The housing and the panel together surround the intermediate body, the printed circuit board and the control apparatus, and the housing provides pressure to ensure that the intermediate body and the sound-receiving surface of the acoustic sensor are pressed tightly against each other.

According to another aspect of the present invention, the present invention also relates to a household electric appliance comprising the abovementioned acoustic touch-control system. As alternatives, the household electric appliance may for example be a washing machine, dishwasher, electric refrigerator, air conditioning, induction cooker or gas cooker, etc.

Other features which are considered as characteristic for the invention are set forth in the appended claims.

Although the invention is illustrated and described herein as embodied in an acoustic touch-control system, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1A is a top schematic view of a touch panel according to the invention;

FIG. 1B is a diagrammatic, sectional view of an acoustic touch-control system according to the invention;

FIG. 2 is a graph showing signal outputs of acoustic sensors;

FIG. 3 is an illustration showing a demonstrative arrangement view of acoustic sensors together with auxiliary acoustic sensors;

FIG. 4 is a sectional view of a first embodiment of the acoustic touch-control system according to the invention;

FIG. 5 is a sectional view of a second embodiment of the acoustic touch-control system according to the present invention;

FIG. 6 is a sectional view of a third embodiment of the acoustic touch-control system according to the invention;

FIG. 7 is a sectional view of a fourth embodiment of the acoustic touch-control system according to the invention;

FIG. 8 is a sectional view of a fifth embodiment of the acoustic touch-control system according to the invention;

FIG. 9 is a sectional view of a sixth embodiment of the acoustic touch-control system according to the invention; and

FIG. 10 is a sectional view of a seventh embodiment of an acoustic touch-control system according to the invention.

### DETAILED DESCRIPTION OF THE INVENTION

Embodiments of the present invention are expounded further below demonstratively with the aid of the accompanying drawings. The particular embodiments of the present invention are intended to facilitate further explanation of the concept of the present invention, the technical problem solved, the technical features forming the technical solution, and the technical effects produced. It must be explained that the various features thus obtained are not restricted to the various embodiments, but may be linked and/or combined with various other described features and/or various features in other embodiments. The various details in the drawings should be understood as being merely explanatory, not limiting.

An acoustic touch-control system according to the present invention principally detects, by means of one or more acoustic sensors, a sound wave generated by knocking or tapping a touch panel, and precisely locates a position of knocking or tapping on the basis of a detected sound wave signal. Thus, based on the fundamental principles of an acoustic touch-control system, the acoustic touch-control system according to the present invention is a reliable touch-control system that can be applied widely. Specifically, the acoustic touch-control system is suitable for a wide range of touching object types, can use panels of different material types, and is not affected by dampness or the magnitude of pressure, etc.

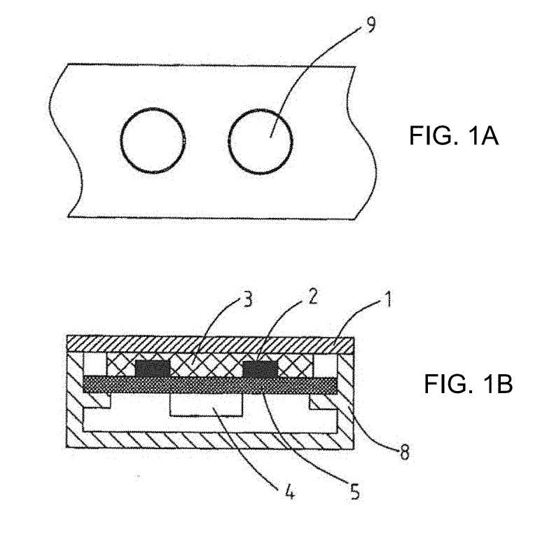

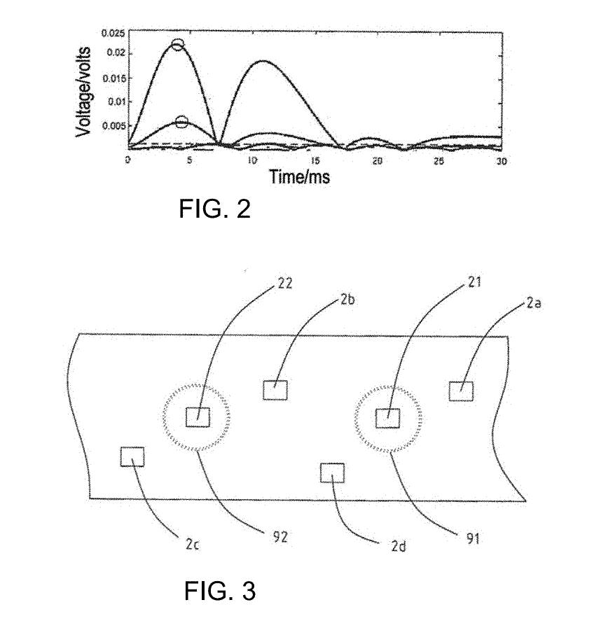

An acoustic touch-control system according to the present invention is described in detail below with reference to FIGS. 1A, 1B and 2.

FIG. 1A shows a schematic diagram of a touch panel according to the present invention. As shown in FIG. 1A, two touch regions 9 are present demonstratively on the touch panel 1. Based on the fundamental principles of an acoustic touch-control system, a wide range of panel types may be used here, e.g. metal, plastic, glass or wood. Here, each touch region may represent one function, e.g. corresponding functions may be activated by knocking or tapping the touch regions. It must be pointed out that a touching body used to execute a knocking or tapping action may have a wide range of types, e.g. the touching body may involve multiple different types of object, e.g. may be a human body, such as a finger (including a finger wearing a plastic glove); a non-conductive object, such as a plastic object; or a conductive object, such as a metal rod, etc. Of course, a greater number of touch regions 9 representing different functions could also be provided on the touch panel 1 (taking a washing machine as an example, one touch region 9 could for example be provided for each of a number of different functions such as quick wash, rinse or intensive wash).

FIG. 1B shows a sectional schematic diagram of an acoustic touch-control system according to the present invention. As shown in FIG. 1B, the acoustic touch-control system demonstratively contains the panel 1, an acoustic sensor 2, a control apparatus 4, an intermediate body 3 and a housing 8. Here, the acoustic touch-control system is demonstratively provided with two acoustic sensors 2. The acoustic sensors 2 are respectively allocated to corresponding touch regions 9. A side of the panel facing a user is defined as a front side. The acoustic sensors 2 are disposed on a back side of the panel 1, preferably centrally disposed in underlying regions corresponding to the corresponding touch regions 9. The acoustic sensor 2 is preferably formed as a MEMS microphone. A MEMS microphone is a microphone manufactured on the basis of MEMS technology, and has improved noise elimination properties and good radio frequency (RF) and electromagnetic interference (EMI) suppression capability. In addition, as can be seen from FIG. 1B, the two MEMS microphones are demonstratively disposed on a printed circuit board 5. At the same time, the control apparatus 4 is also demonstratively disposed on the printed circuit board 5. It must be pointed out that in the scope of the present application, the “control apparatus” may be a controller comprising a memory (e.g. RAM, ROM, EPROM, EEPROM, flash memory or other solid-state memory), a processor (e.g. CPU, DSP, etc.) and an input/output device, could also be a control circuit formed of discrete analogue electronic devices and/or digital electronic devices, and could even be an application-specific integrated circuit (ASIC). Of course, various other types of device could also be imagined to be integrated on the printed circuit board 5. Here, the printed circuit board 5 not only serves the function of integrating the devices, thereby simplifying wiring and reducing space demands, but also serves the function of a support for the devices.

In addition, it can be seen from FIG. 1B that the intermediate body is disposed between the touch panel 1 and the printed circuit board 5. The function of the intermediate body 3 is principally to hermetically isolate a sound-receiving surface of the acoustic sensor 2 from the external environment. It must be explained that the hermetic isolation of the sound-receiving surface of the acoustic sensor 2 from the external environment means that: the intermediate body 3 is formed such that no air gap in communication with the external environment is present between the sound-receiving surface of the acoustic sensor 2 and the panel, thereby ensuring that noise from the external environment will not be transmitted via an air gap directly to the sound-receiving surface of the acoustic sensor 2, and thereby interfere with the acoustic sensor 2. All interference factors, e.g. noise from a road, etc., in an atmospheric environment or sound field in which the entire acoustic touch-control system is located are excluded through the hermetic isolation of the sound-receiving surface of the acoustic sensor 2 from the external environment. Here, the intermediate body may for example be made from silicone rubber or foam. In addition, the Shore hardness of the intermediate body is in the range of 50 to 110, preferably in the range of 70 to 90, and more preferably in the range of 75 to 85. An intermediate body material which is too soft or too hard will affect the performance of the system. If the intermediate body material is too soft, a sound wave produced by knocking or tapping the touch region might be absorbed by the intermediate body, with the result that the acoustic sensor is unable to receive a sound wave signal, or a sound wave signal received is too small so that the control apparatus is unable to make an accurate determination. However, if the intermediate body material is too hard, a sound wave produced by knocking or tapping the touch region might be held in the intermediate body continuously, thereby possibly increasing the difficulty of analytical processing by the control apparatus, and possibly even causing errors in determination by the control apparatus. The hardness selected in the present invention can not only effectively conduct sound wave signals to the acoustic sensor, but also enable sound wave signals to die out within a suitable time period. Here, the “suitable time period” relates to the control apparatus; for different embodiments of the control apparatus, hardnesses adapted thereto may be selected, in order to enable the control apparatus to subject received sound wave signals to further analytical processing effectively.

In addition, it can be seen from FIG. 1B that the acoustic touch-control system is further provided with a U-shaped housing 8; the housing is formed to accommodate the intermediate body 3, the printed circuit board 5 and the control apparatus 4, and the housing and the touch panel 1 together close the entire system. It can be seen from FIG. 1b that the housing 8 is formed with two shoulders, and the printed circuit board 5 is disposed on the two shoulders. When assembly is carried out, the housing 8 and the touch panel 1 are pressed tightly, thereby providing pressure to ensure that the intermediate body 3 and the printed circuit board 5 or the sound-receiving surface of the acoustic sensor 2 are pressed tightly together, and thereby further ensuring hermetic isolation from the external environment, i.e. that no communicative air gap is present.

An operating process of the acoustic touch-control system is expounded demonstratively below. For example, in order to trigger a function (e.g. a rinse function) represented by a left-side touch region 9 in FIG. 1a, the user can knock or tap the touch region 9 located at the left side of FIG. 1a on the touch panel 1. A sound wave is thereby generated at a corresponding knocked or tapped position. The sound wave will then be conducted directly from the touch panel 1 to the sound-receiving surface of the acoustic sensor 2 on the left side in FIG. 1b via the intermediate body 3; in the case of the current embodiment, no air gap is present in a conduction path of the sound wave. Here, the acoustic sensor of the touch region 9 on the left side in FIG. 1a first detects the sound wave generated by knocking or tapping. The acoustic sensor then transmits the detected sound wave in the form of an electrical signal to the control apparatus 4 in a wired or wireless manner. Based on the electrical signal received, the control apparatus 4 determines that the user has operated the touch region 9 on the left side in FIG. 1A, and on this basis can activate the function (e.g. rinse function) represented thereby.

Here, the acoustic sensor 2 on the right side in FIG. 1B might also receive a sound wave and also transmit the detected sound wave in the form of an electrical signal to the control apparatus 4 in a wired or wireless manner. The control apparatus may determine the touch region 9 which has been directly knocked or tapped on the basis of the chronological order in which the acoustic sensors receive sound wave signals, the amplitudes of the sound wave signals received, the phases of the sound wave signals, and attenuation characteristics of the sound wave signals.

To explain this point, FIG. 2 shows demonstratively a graph of signal outputs of the acoustic sensors. In FIG. 2, the vertical coordinate is an output voltage of the acoustic sensor (units: volts), and the horizontal coordinate is time (units: ms). It can be seen from FIG. 2 that the sound waves are attenuated continuously with time. The sensor which detects the sound wave first outputs the largest voltage signal; for example, in the case of the current embodiment, the peak value of the voltage signal is about 0.022 volts. The sensor which detects the sound wave later outputs a smaller voltage signal; for example, in the case of the current embodiment, the peak value of the voltage signal is about 0.005 volts. The control apparatus 4 can then determine the corresponding knocked or tapped touch region 9 on the basis of the voltage signal amplitudes, and thereby trigger the corresponding function (e.g. activate a rinse mode). Advantageously, in addition to the amplitudes of the sound wave signals, many variable factors such as the chronological order, phases and attenuation characteristics of sound wave signals may also be taken into account. For example, in the case of the current embodiment, the amplitudes, chronological order, phases and attenuation characteristics of received signals of the acoustic sensors 2 are recorded separately in the control apparatus. On this basis, the control apparatus can then be provided with an algorithm for filtering and determination (e.g. by a fuzzy control algorithm), for the purpose of increasing the precision with which a touch-control operation can be located, to better determine the touch region which has been knocked or tapped.

In order to further improve the operating performance of the entire system, one or more auxiliary acoustic sensors may be additionally provided for each touch region. The reason is that e.g. vibration from a device itself (the acoustic touch-control system being mounted on the device) or inadvertent or accidental knocking or tapping outside the touch region might erroneously trigger the corresponding function.

FIG. 3 shows a demonstrative arrangement view of acoustic sensors together with auxiliary acoustic sensors. Here, auxiliary acoustic sensors 2a, 2b, 2c and 2d are arranged around the acoustic sensors 21, 22, which are allocated to corresponding touch regions 91, 92. The control apparatus for example can exclude interference on the basis of amplitudes and/or phases of signals from the acoustic sensors 21, 22 and the auxiliary acoustic sensors 2a, 2b, 2c, 2d. When the device itself vibrates, all the sensors, i.e. the acoustic sensors together with the auxiliary acoustic sensors, obtain similar signals. However, for example when a finger knocks or taps a corresponding touch region 91, the corresponding acoustic sensor 21 obtains the strongest signal. Interference caused by vibration of the device itself can be excluded on the basis of the divergence expounded in relation to FIG. 2. Similarly, when knocking or tapping occurs outside the touch regions, e.g. when knocking or tapping occurs close to the auxiliary acoustic sensor 2a, the acoustic sensor 21 also has a relatively large signal, but this signal is smaller than a signal of the auxiliary acoustic sensor 2a, and interference can thereby be excluded. It must be explained that the scenarios described above should be understood merely as demonstrative explanations; various other improvements at the algorithm level may also be imagined, in order to better and more efficiently exclude different interference factors.

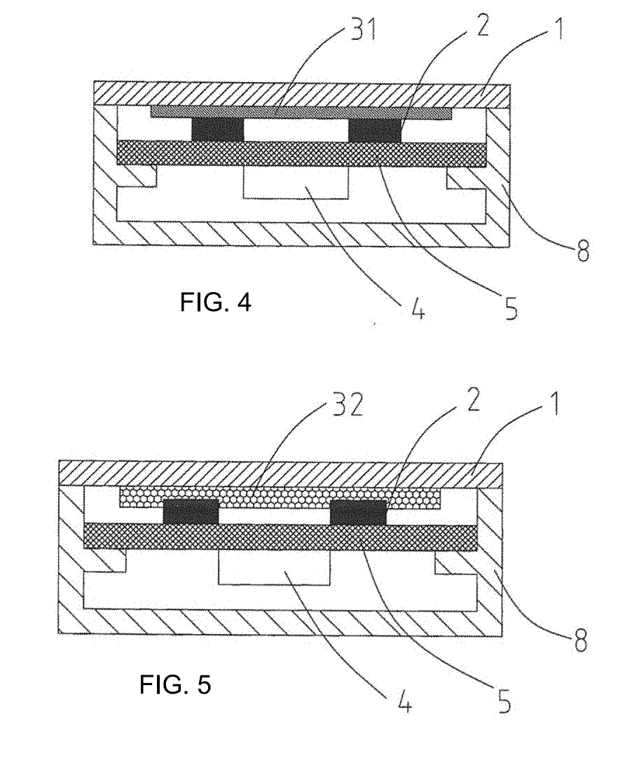

FIG. 4 shows a first embodiment of an acoustic touch-control system according to the present invention. As shown in FIG. 4, the acoustic touch-control system demonstratively contains the panel 1, the printed circuit board 5, the control apparatus 4, an intermediate body 31 and the housing 8. Two acoustic sensors 2 are demonstratively provided on the printed circuit board 5. The control apparatus 4 is arranged to receive signals from the acoustic sensors 2 and subject the signals to further analytical processing. Here, the intermediate body 31 is made of a silicone rubber member having a Shore hardness in the range of 50 to 110, preferably in the range of 70 to 90, and more preferably in the range of 75 to 85. It can be seen from FIG. 4 that a sound-receiving surface of the acoustic sensor can press hermetically into the silicone rubber member, based on material characteristics of the silicon rubber member and pressure provided by the housing, such that no air gap is present between the silicone rubber member and the sound-receiving surface of the acoustic sensor. Preferably, the silicone rubber member may be connected to the printed circuit board 5 and/or the panel 1 by bonding, in particular by means of a bonding layer. In this embodiment, sound waves are conducted to the acoustic sensors from a touch panel via the silicone rubber member. Preferably, sound waves are conducted to the acoustic sensors from the touch panel via a bonding layer and then via the silicone rubber member.

FIG. 5 shows a second embodiment of an acoustic touch-control system according to the present invention. As shown in FIG. 5, the acoustic touch-control system demonstratively contains the panel 1, the printed circuit board 5, the control apparatus 4, an intermediate body 32 and the housing 8. Two acoustic sensors 2 are demonstratively provided on the printed circuit board 5. The control apparatus 4 is arranged to receive signals from the acoustic sensors 2 and subject the signals to further analytical processing. Here, the intermediate body 32 is made of foam having a Shore hardness in the range of 50 to 110, preferably in the range of 70 to 90, and more preferably in the range of 75 to 85. Of course, other closed-cell foamed materials could also be imagined, e.g. stone wool, mineral wool, etc. It can be seen from FIG. 5 that a sound-receiving surface of the acoustic sensor can extend into or be sunk into the foam, based on material characteristics of the foam and pressure provided by the housing, such that there is hermetic contact between the foam and the sound-receiving surface of the acoustic sensor, i.e. no air gap is present. Preferably, the foam may be connected to the printed circuit board 5 and/or the panel 1 by bonding, in particular by a bonding layer. In this embodiment, sound waves are conducted to the acoustic sensors from a touch panel via the foam layer. Preferably, sound waves are conducted to the acoustic sensors from the touch panel via a bonding layer and then via the foam layer.

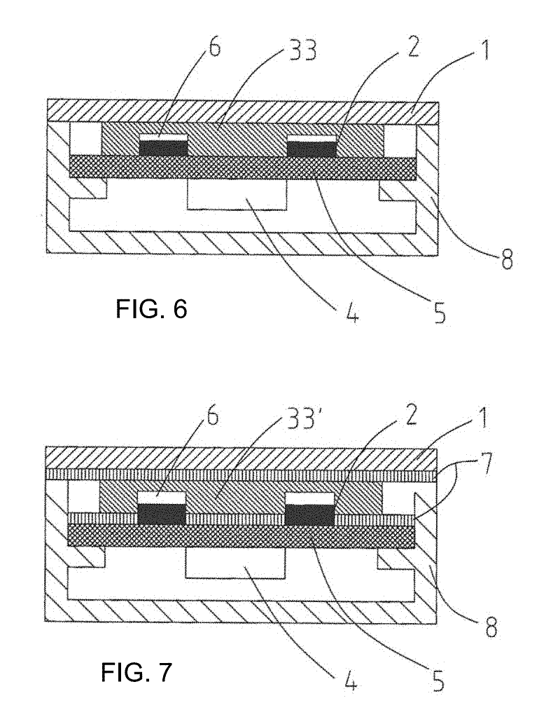

FIG. 6 shows a third embodiment of an acoustic touch-control system according to the present invention. As shown in FIG. 6, the acoustic touch-control system demonstratively contains the panel 1, the printed circuit board 5, the control apparatus 4, a intermediate body 33 and the housing 8. Two acoustic sensors 2 are demonstratively provided on the printed circuit board 5. The control apparatus 4 is arranged to receive signals from the acoustic sensors 2 and subject the signals to further analytical processing. Here, the intermediate body 33 is made of a silicone rubber member; the silicone rubber member is formed as a planar structure having blind holes by low-pressure injection molding. As can be seen from FIG. 6, the depth of the blind holes is greater than the thickness of the acoustic sensors 2, and the acoustic sensors 2 are respectively inserted into corresponding blind holes, such that only a closed cavity 6 is present between a sound-receiving surface of the acoustic sensor 2 and the panel 1. Here, the presence of the cavity 6 is advantageous, because it can prevent the sound-receiving surface of the acoustic sensor from being pressed during system operation and therefore protect the acoustic sensor, extending the service life thereof. In this embodiment, sound waves are conducted to the acoustic sensor from a touch panel via the silicone rubber member and then via the cavity.

FIG. 7 shows a fourth embodiment of an acoustic touch-control system according to the present invention. Added to the third embodiment of the acoustic touch-control system according to the present invention, an intermediate body 33′ of the acoustic touch-control system in FIG. 7 is connected to the printed circuit board 5 and panel 1 by means of two bonding layers 7 respectively, thereby further enhancing airtightness. In this embodiment, sound waves are conducted to the acoustic sensor from a touch panel via the bonding layer, then via the silicone rubber member, and then via the cavity.

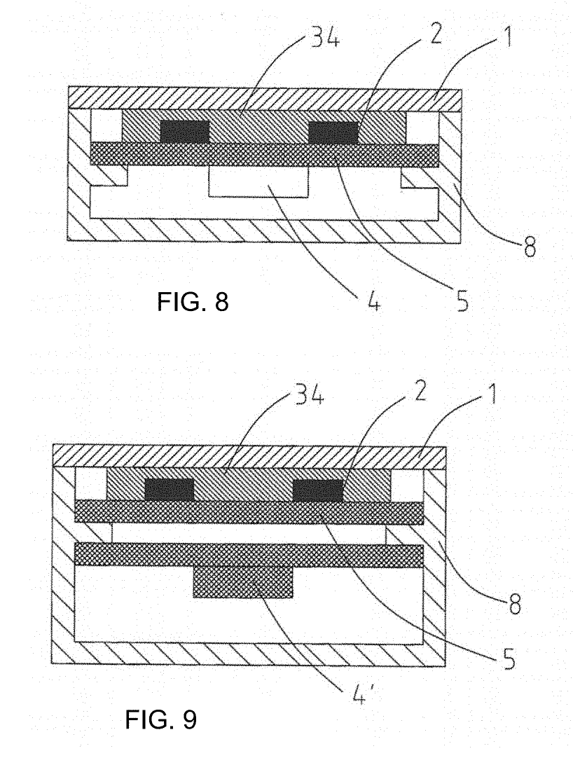

FIG. 8 shows a fifth embodiment of an acoustic touch-control system according to the present invention. As shown in FIG. 8, the acoustic touch-control system demonstratively contains the panel 1, the printed circuit board 5, the control apparatus 4, an intermediate body 34 and the housing 8. Two acoustic sensors 2 are demonstratively provided on the printed circuit board 5. The control apparatus 4 is arranged to receive signals from the acoustic sensors 2 and subject the signals to further analytical processing. Here, the intermediate body 34 is made of a silicone rubber member; the silicone rubber member is injection-molded on the printed circuit board by low-pressure injection molding, so that the printed circuit board (including the acoustic sensors disposed on the printed circuit board) and the silicone rubber member are integrally formed, and an air gap between a sound-receiving surface of the acoustic sensor and the silicone rubber member is therefore eliminated. In a similar manner, the silicone rubber member and the panel may be integrally formed, and an air gap between the intermediate body and the panel is therefore eliminated. Of course, the silicone rubber member and the panel could also be connected by press-joining or bonding. In this embodiment, sound waves are conducted to the acoustic sensors from a touch panel via the silicone rubber member.

FIG. 9 shows a sixth embodiment of an acoustic touch-control system according to the present invention. As shown in FIG. 9, the acoustic touch-control system demonstratively contains the panel 1, the printed circuit board 5, the control apparatus 4′, an intermediate body 34 and the housing 8. Two acoustic sensors 2 are demonstratively provided on the printed circuit board 5. The control apparatus 4′ is arranged to receive signals from the acoustic sensors 2 and subject the signals to further analytical processing. It can be seen from FIG. 9 that the control apparatus 4′ is separate from the printed circuit board 5. Here, the control apparatus 4′ is demonstratively disposed on another printed circuit board. Here, the acoustic sensor 2 and the control apparatus 4′ may communicate in a wired or wireless manner.

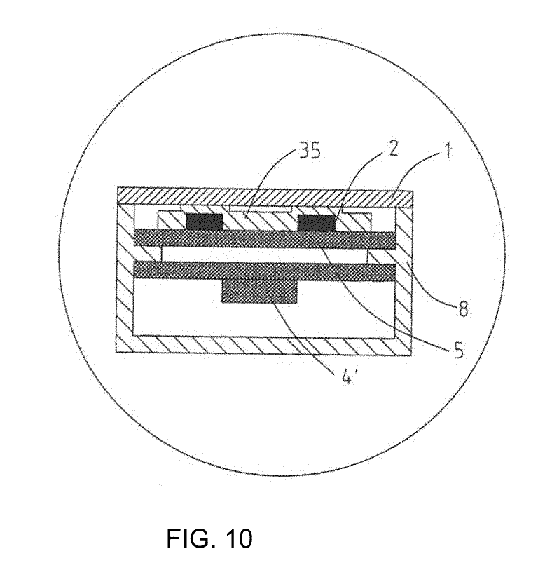

FIG. 10 shows a seventh embodiment of an acoustic touch-control system according to the present invention. As shown in FIG. 10, the acoustic touch-control system demonstratively comprises the panel 1, the printed circuit board 5, the control apparatus 4′, an intermediate body 35 and the housing 8. Two acoustic sensors 2 are demonstratively provided on the printed circuit board 5. The control apparatus 4′ is arranged to receive signals from the acoustic sensors 2 and subject the signals to further analytical processing. Here, the intermediate body 35 is made of a silicone rubber member; the silicone rubber member is formed as a planar structure having blind holes by low-pressure injection molding. As can be seen from FIG. 10, the depth of the blind holes is less than the thickness of the acoustic sensors 2, and the acoustic sensors 2 are respectively inserted into corresponding blind holes, such that the silicone rubber member is in hermetic contact with the panel 1 only in partial regions, preferably in a boss-like fashion. It must be pointed out that having the silicone rubber member in full-surface hermetic contact with the panel would increase manufacturing difficulty and thereby increase costs. Hence, here it is very advantageous to only take into account hermetic contact between the panel and the silicone rubber member in regions corresponding to the blind holes, i.e. in regions of the sound-receiving surfaces of the acoustic sensors. In addition, it can also be seen from FIG. 10 that the control apparatus 4′ is separate from the printed circuit board 5. Here, the control apparatus 4′ is demonstratively disposed on another printed circuit board. Here, the acoustic sensor 2 and the control apparatus 4′ may communicate in a wired or wireless manner. In this embodiment, sound waves are conducted to the acoustic sensors from a touch panel via the silicone rubber member (or bosses of the silicone rubber member).

The present invention is not limited to the embodiments shown, but includes or extends to all technical equivalents which can fall into the effective scope of the attached claims. Descriptions of position selected in the description, such as upper, lower, left and right, etc. refer to the accompanying drawings which are directly described and shown, and can be transferred to new positions according to meaning if a change in position occurs.

1. An acoustic touch-control system, comprising:
a panel having a touch region;
an acoustic sensor respectively allocated to said touch region and having a sound-receiving surface;
a control apparatus disposed to receive a signal from said acoustic sensor and subject the signal to further analytical processing; and
an intermediate body capable of hermetically isolating said sound-receiving surface of said acoustic sensor from an external environment.

2. The acoustic touch-control system according to claim 1, further comprising a printed circuit board, said acoustic sensor is disposed on said printed circuit board, and said intermediate body is disposed between said panel and said printed circuit board.

3. The acoustic touch-control system according to claim 2,
further comprising a housing accommodating said intermediate body, said printed circuit board and said control apparatus; and
wherein said housing and said panel are formed such that said intermediate body and said printed circuit board are pressed tightly against each other.

4. The acoustic touch-control system according to claim 1, wherein:
said acoustic sensor is one of a plurality of acoustic sensors having sound-receiving surfaces; and
said intermediate body is formed such that said sound-receiving surfaces of said plurality of acoustic sensors are hermetically isolated from each other.

5. The acoustic touch-control system according to claim 1, wherein said intermediate body is one of a plurality of intermediate bodies, each of said intermediate bodies is respectively allocated to said acoustic sensor.

6. The acoustic touch-control system according to claim 1, wherein said intermediate body circumferentially surrounds said sound-receiving surface of said acoustic sensor.

7. The acoustic touch-control system according to claim 1, wherein said intermediate body is in hermetic contact with said sound-receiving surface of said acoustic sensor.

8. The acoustic touch-control system according to claim 1, wherein said intermediate body is formed as a planar structure having a blind hole formed therein, wherein a depth of said blind hole is less than a thickness of said acoustic sensor, and said acoustic sensor is disposed in said blind hole, such that said intermediate body is in hermetic contact with said panel only in a partial region.

9. The acoustic touch-control system according to claim 1, wherein said intermediate body is a planar structure having a blind hole formed therein, a depth of said blind hole is greater than a thickness of said acoustic sensor, and said acoustic sensor is disposed in said blind hole, such that only a closed cavity is present between said sound-receiving surface of said acoustic sensor and said panel.

10. The acoustic touch-control system according to claim 1, wherein said intermediate body is connected to said printed circuit board and/or said panel by injection molding.

11. The acoustic touch-control system according to claim 1, wherein said intermediate body is connected to said printed circuit board and/or said panel by bonding.

12. The acoustic touch-control system according to claim 1, wherein said intermediate body is made of an elastic material.

13. The acoustic touch-control system according to claim 1, wherein a Shore hardness of said intermediate body is in a range of 50 to 110.

14. The acoustic touch-control system according to claim 1, wherein said control apparatus is disposed on said printed circuit board, or said control apparatus is separate from said printed circuit board, and said acoustic sensor communicates with said control apparatus.

15. The acoustic touch-control system according to claim 1, further comprising an auxiliary acoustic sensor disposed around said acoustic sensor and allocated to said touch region.

16. The acoustic touch-control system according to claim 15, wherein said control apparatus can increase a precision with which a touch operation is located on a basis of amplitudes and/or a chronological order and/or phases and/or attenuation characteristics of signals from said acoustic sensor and said auxiliary acoustic sensor.

17. The acoustic touch-control system according to claim 1, wherein said panel is made of metal, plastic, glass or wood.

18. The acoustic touch-control system according to claim 1, wherein said acoustic sensor is a microphone.

19. A household electric appliance, comprising:
the acoustic touch-control system according to claim 1.

20. The household electric appliance according to claim 19, wherein the household electric appliance is selected from the group consisting of a washing machine, a dishwasher, an electric refrigerator, an air conditioner, an induction cooker and a gas cooker.
